(19) United States
(12) Patent Application Publication
(10) Pub. No.: US 2025/0226669 A1
(43) Pub. Date: Jul. 10, 2025

(54) SYSTEMS AND METHODS FOR MICRO-REACTOR POWER GENERATION IN DATACENTERS

(71) Applicant: Microsoft Technology Licensing, LLC, Redmond, WA (US)

(72) Inventors: Ehsan NASR AZADANI, Sammamish, WA (US); Phillip Todd NOE, Hixson, TN (US); Christian L. BELADY, Mercer Island, WA (US); Winston Allen SAUNDERS, Seattle, WA (US)

(21) Appl. No.: 18/404,717

(22) Filed: Jan. 4, 2024

(51) Int. Cl. H02J 3/46

(52) U.S. Cl. CPC H02J 3/46

(57) ABSTRACT

A datacenter power system may include a co-location including a plurality of computing devices. A datacenter power system may include a micro-plant in electrical communication with the co-location to supply micro-plant electrical power to the co-location, the micro-plant including: a plurality of micro-reactors, wherein each micro-reactor is configured to produce thermal energy, and at least one generator in thermal communication with the plurality of micro-reactors configured to convert at least a portion of the thermal energy to the micro-plant electrical power.

### BACKGROUND

Datacenters require a robust electrical power system to meet the power demands of highly variable computational loads. Datacenters demand highly reliable power sources to ensure sufficient uptime. On-site power generation and distribution can allow a datacenter to limit reliance on regional utility systems.

### BRIEF SUMMARY

In some aspects, the techniques described herein relate to a datacenter power system including: a co-location including a plurality of computing devices; and a micro-plant in electrical communication with the co-location to supply micro-plant electrical power to the co-location, the micro-plant including: a plurality of micro-reactors, wherein each micro-reactor is configured to produce thermal energy, and at least one generator in thermal communication with the plurality of micro-reactors configured to convert at least a portion of the thermal energy to the micro-plant electrical power.

In some aspects, the techniques described herein relate to a datacenter power system including: a grid connection configured to receive power from a regional power grid; one or more co-locations including a plurality of computing devices; a micro-plant in electrical communication with the grid connection and the co-location to supply micro-plant electrical power to the grid connection and the co-location, the micro-plant including: a plurality of micro-reactors, wherein each micro-reactor is configured to produce thermal energy, at least one generator in thermal communication with the plurality of micro-reactors configured to convert at least a portion of the thermal energy to the micro-plant electrical power, and a micro-plant controller in communication with the grid connection, the co-location, and the at least one generator, wherein the micro-plant controller is configured to: receive co-location demand information, receive grid information, and adjust an output of micro-plant electrical power based at least partially on the co-location demand information and the grid information.

In some aspects, the techniques described herein relate to a datacenter power system including: a first datacenter region including: a first co-location including a plurality of computing devices; a first micro-plant in electrical communication with a first grid connection and the co-location to supply first micro-plant electrical power to the first grid connection and the first co-location, the first micro-plant including: a plurality of micro-reactors, wherein each micro-reactor is configured to produce first thermal energy, and at least one generator in thermal communication with the plurality of micro-reactors configured to convert at least a portion of the first thermal energy to the first micro-plant electrical power; a second datacenter region including: a second co-location including a plurality of computing devices; a second micro-plant in electrical communication with a second grid connection and the second co-location to supply second micro-plant electrical power to the second grid connection and the second co-location, the second micro-plant including: a plurality of micro-reactors, wherein each micro-reactor is configured to produce second thermal energy, and at least one generator in thermal communication with the plurality of micro-reactors configured to convert at least a portion of the thermal energy to the second micro-plant electrical power; and a micro-grid controller in data communication with the regional power grid, the first datacenter region, and the second datacenter region, wherein the micro-grid controller is configured to: receive first datacenter region balance information, receive second datacenter region balance information, and adjust electrical power between the first datacenter region and the second datacenter region through the micro-grid based at least partially on the datacenter region balance information.

This Summary is provided to introduce a selection of concepts in a simplified form that are further described below in the Detailed Description. This Summary is not intended to identify key features or essential features of the claimed subject matter. Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a schematic representation of a conventional datacenter power system.

FIG. 2 is a schematic diagram of an embodiment of a datacenter power system including a plurality of datacenter regions.

FIG. 3 is a diagram of an embodiment of a micro-grid with electrical conduits that communicate micro-grid electrical power between datacenter regions.

FIG. 4 is a diagram of an embodiment of a datacenter power system including a micro-grid that is independent of a regional power grid.

FIG. 5 is a schematic flow diagram of an embodiment of a datacenter (or datacenter region) at least partially powered by a micro-plant including a plurality of micro-reactors and conversion generators.

FIG. 6 is a schematic flow diagram of an embodiment of a datacenter (or datacenter region) at least partially powered by a micro-plant including a plurality of micro-reactors with a thermal manifold distributing the thermal energy to a plurality of conversion generators.

FIG. 7 is a schematic representation of another embodiment of a datacenter region with a micro-plant that generates electricity at a medium voltage.

FIG. 8 is a schematic representation of a micro-reactor or micro-plant of micro-reactors within an embodiment of a datacenter power system.

### DETAILED DESCRIPTION

The present disclosure generally relates to systems and methods for providing electrical power to a datacenter. Conventional datacenters rely on regional power grids to supply electricity to the datacenter. A reliance on regional power grid can leave the datacenter susceptible to failures of the regional power grid, variations in demand on the power grid, variations in the supply to the power grid, variations to the carbon load of the regional power grid, and other properties of the regional power grid that out of the control of the designers or operators of the datacenter. On-site power generation allows the datacenter to limit or eliminate dependency on the regional power grid and even allow the datacenter to export power to the regional power grid. In some embodiments, power distribution efficiency is increased by having on-site power generation by limiting the distance the electricity is transported to or within the datacenter. In some embodiments, power generation efficiency is increased by generating power based on the current or anticipated power demands of the datacenter. In at least one embodiment, on-site power generation allows a datacenter to operate without a grid connection to a regional power grid.

In some embodiments, a datacenter power system, according to the present disclosure, includes at least one micro-reactor plant (“micro-plant”) including a plurality of micro-reactors. In some examples, a micro-reactor generates no more than 20 Megawatts (MW) of power. In some examples, the micro-reactor generates thermal energy, and a turbine or other conversion generator converts the thermal energy to electricity. In some examples, the micro-reactor is a nuclear micro-reactor. In some example, the micro-reactor is a combustion reactor. In some examples, the micro-reactor is a nuclear fission reactor. In some examples, the micro-reactor is a nuclear fusion reactor.

In some embodiments, the micro-plant includes a conversion generator for each of the micro-reactors. In some examples, the micro-plant includes a single conversion generator for each micro-reactor such as a 1:1 ratio of conversion generators to micro-reactors. In some examples, the micro-plant includes at least one conversion generator for each micro-reactor. In some examples, the micro-plant includes more conversion generators than micro-reactors. In some embodiments, at least one of the micro-reactors is directly coupled to a unique conversion generator. In some embodiments, each of the micro-reactors is directly coupled to an individual conversion generator. In some embodiments, the micro-plant has a thermal manifold or thermal bus that receives thermal energy from a plurality of micro-reactors. In some examples, the thermal manifold receives thermal energy from the plurality of micro-reactors and distributes the thermal energy to one or more conversion generators. In some examples, the thermal manifold receives thermal energy from the plurality of micro-reactors and distributes the thermal energy to a plurality of conversion generators that includes at least one conversion generator for each micro-reactor. In some examples, the thermal manifold receives thermal energy from the plurality of micro-reactors and distributes the thermal energy to a plurality of conversion generators that includes a greater quantity of conversion generators than micro-reactors in the plurality of micro-reactors.

In some embodiments, the micro-plant includes valves to selectively limit and/or control the transfer of heat from the plurality of micro-reactors to the plurality of conversion generators. For example, a micro-reactor heats a fluid with thermal energy, and the fluid carries the thermal energy to the conversion generator to convert the thermal energy to electricity. In some examples, one or more thermal valves between the micro-reactor and the conversion generator can control the amount of fluid and/or thermal energy is delivered to the conversion generator. In some examples, one or more micro-reactor thermal valves limits or prevents fluid and/or thermal energy from moving from the micro-reactor(s) to the thermal manifold before the conversion generator(s). In some examples, one or more generator thermal valves limits or prevents fluid and/or thermal energy from moving from the thermal manifold to the conversion generator(s). In some examples, a combination of micro-reactor thermal valves and generator thermal valves can selectively route the fluid and/or thermal energy from one or more micro-reactors of the plurality of micro-reactors to one or more conversion generators of the plurality of conversion generators.

The micro-plant has a micro-plant controller configured to adjust the electricity output of the micro-plant. In some embodiments, the micro-plant controller controls the thermal output of the micro-reactors. For example, the micro-plant controller adjusts the fuel delivery of the micro-reactor(s) of the micro-plant. For example, the micro-plant controller adjusts the combustion rate of the micro-reactor(s) of the micro-plant. For example, the micro-plant controller adjusts the rate of fission or reactivity, such as with control material, of the micro-reactor(s) of the micro-plant.

In some embodiments, the micro-plant controller controls one or more thermal valves between the micro-reactors and the conversion generator. As described above, the thermal valves can selectively route or limit the movement of fluid and/or thermal energy from the micro-reactor(s) to the conversion generator(s) of the micro-plant. In some embodiments, the micro-plant controller selectively routes at least a portion of the thermal energy to a thermal energy store for later conversion to electricity.

In some embodiments, the micro-plant controller controls the electricity distribution after the conversion generators. In some embodiments, the micro-plant controller directs at least a portion in the electricity generated by the conversion generator(s) to a power distribution system of the datacenter. In some embodiments, the micro-plant controller directs at least a portion of the electricity generated by the conversion system to an electricity store, such as a battery. In some embodiments, the micro-plant controller directs at least a portion in the electricity generated by the conversion generator(s) to a grid connection for exportation to the regional power grid. In some embodiments, at least a portion of the electricity is directed to another micro-plant or another datacenter region within a micro-grid including a plurality of micro-plants.

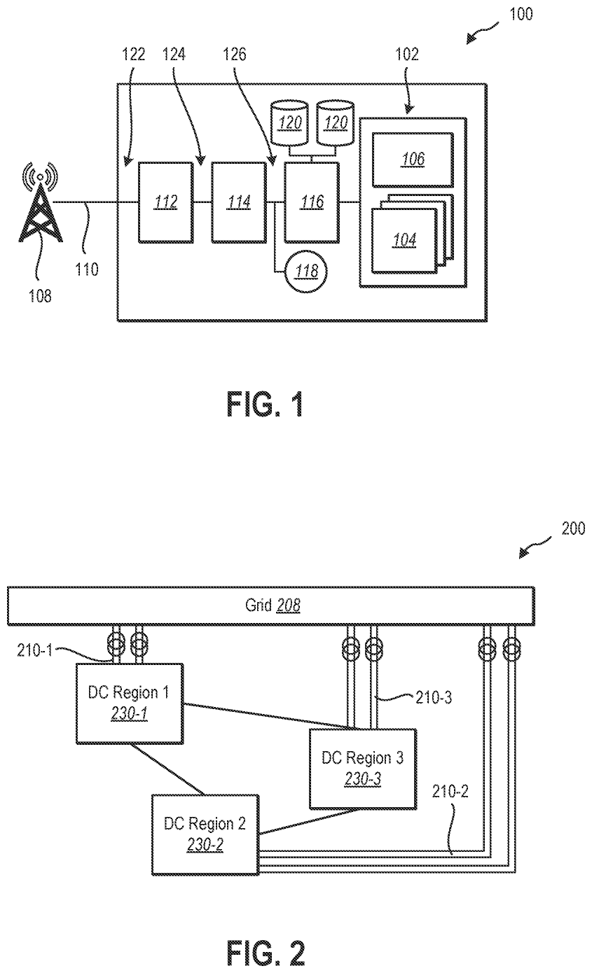

FIG. 1 is a system diagram of a conventional system for providing and managing electrical power in a datacenter. The datacenter power system 100 provides electrical power to, among other portions of the datacenter, one or more co-locations 102. The co-locations 102 include a plurality of computing devices 104. In some examples, the co-location 102 includes a power supply unit (PSU) 106 that receives, converts, and distributes electrical power to the computing devices 104.

The datacenter power system 100, in some examples, receives grid electrical power from a regional utility grid 108. The regional utility grid 108 provides the grid electrical power at a higher voltage than the co-location 102 can utilize, and the datacenter power system 100 converts the grid electrical power for use in the co-locations 102 of the datacenter. For example, the datacenter power system 100 receives the grid electrical power through a grid connection 110 to a high voltage transformer 112 that steps the voltage down. In some examples, the datacenter power system 100 then includes a medium voltage transformer 114 and a low voltage transformer 114 to further step the voltage down in stages and the amperage of the electrical current increases with each step down of voltage. The electrical conduits and the datacenter power system 100, as a whole, must compensate for the increased amperage.

For example, as the amperage through a resistive electrical conduit (e.g., copper wire or cable) increases, the resistivity of the resistive electrical conduit converts a portion of the electrical power to heat and other loss mechanisms. The electrical loss and heat generation are undesirable in the datacenter power system 100. In some examples, the datacenter power system 100 may include additional power sources or storage devices, such as a generator 118 and/or battery storage devices 120. In some examples, the additional power sources or storage devices, such as the generator 118 and/or battery storage devices 120, are coupled to the datacenter power system 100 at different stages of the voltage depending on the provided voltage of the additional power sources or storage devices.

In the illustrated example of FIG. 1, the datacenter power system 100 receives a high voltage grid electrical power 122 through the grid connection 110 to the high voltage transformer 112. The incoming grid electrical power 122 is received with a grid voltage, a grid amperage, and a grid frequency. In some examples, the grid voltage is a high voltage no less than 110 kilovolts (kV). In some examples, the grid voltage is an extra-high voltage no less than 345 kV. In some examples, the grid voltage is an ultra-high voltage no less than 1100 kV. Stepping down the grid voltage can produce high amperage, as the voltage and amperage are inversely proportional for a given power (Wattage), assuming limited or no losses during conversion.

For example, stepping down the grid voltage of the grid electrical power 122 through the high voltage transformer 112 to a medium voltage electrical power 124 having a medium voltage ten times less than the grid voltage results in a medium amperage ten times greater than the grid amperage. Further step-downs of the medium voltage electrical power 124 to a low voltage electrical power 126 through the medium voltage transformer 114, and of the low voltage electrical power 126 to a co-location electrical power 128 usable by the co-location 102 through the low voltage transformer 116 can continue increasing the amperage by orders of magnitude. As datacenters commonly consume electrical power on the order of Megawatts, the amperage needs to be managed at each step-down in a conventional datacenter power system 100 to avoid excessive electrical losses and heat generation. In some embodiments, on-site power generation eliminates the need to transmit electricity over long distances, and on-site power generation can provide power a lower voltage than a regional power grid, reducing the need for conversion and managing changes in amperage.

FIG. 2 is a schematic diagram of a datacenter power system 200 including a plurality of datacenter regions 230. In some embodiments, each of the datacenter regions 230 include at least some of the elements described in relation to FIG. 1. For example, the datacenter regions 230-1, 230-2, 230-3 each have at least one grid connection 210-1, 210-2, 210-3 through which each of the datacenter regions 230-1, 230-2, 230-3 receive high voltage electrical power from the regional power grid 208.

In some embodiments, the datacenter regions 230-1, 230-2, 230-3 are in data communication with one another to allow computing allocations and load management between the datacenter regions 230-1, 230-2, 230-3. However, each of the datacenter regions 230-1, 230-2, 230-3 is independently powered by grid connections 210-1, 210-2, 210-3, and each datacenter region 230-1, 230-2, 230-3 is dependent on the stability, availability, and cost of the regional power grid 208.

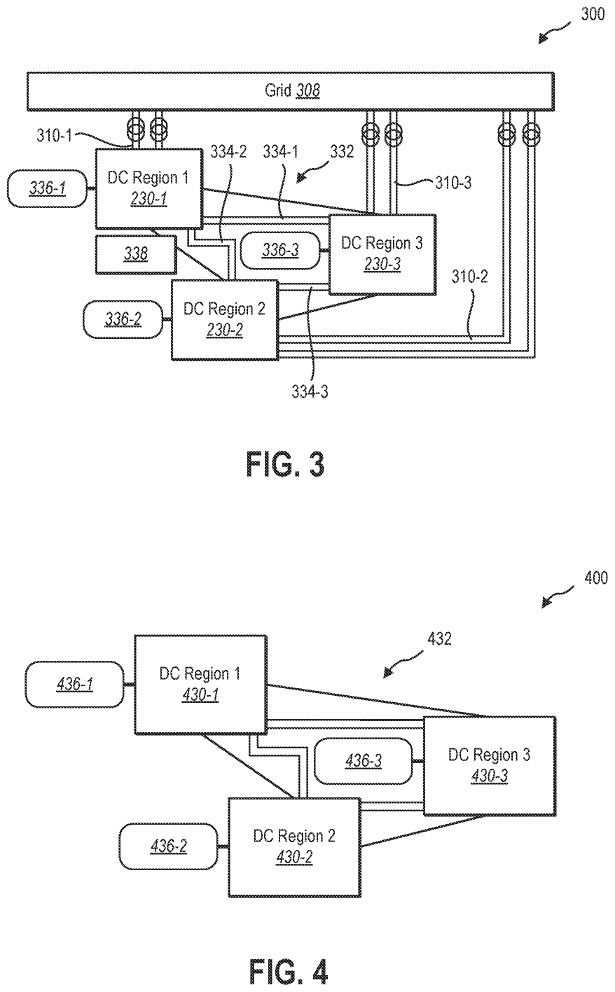

FIG. 3 is a diagram of an embodiment of a micro-grid 332 with electrical conduits 334-1, 334-2, 334-3 that communicate micro-grid electrical power between datacenter regions 330-1, 330-2, 330-3. In some embodiments, each datacenter region 330-1, 330-2, 330-3 has a micro-plant 336-1, 336-2, 336-3 local to the datacenter region 330-1, 330-2, 330-3 that generates micro-plant electrical power, and each datacenter region 330-1, 330-2, 330-3 has a grid connection 310-1, 310-2, 310-3 to a regional power grid 308 to receive grid electrical power.

The datacenter power system 300, therefore, has redundancy in power generation from the regional power grid 308 through the grid connections 310-1, 310-2, 310-3 and from the micro-grid 332 through the electrical conduits 334-1, 334-2, 334-3. In some embodiments, a micro-grid controller 338 balances the electrical power delivery between the micro-plants 336-1, 336-2, 336-3 through the micro-grid 332 and from the grid connections 310-1, 310-2, 310-3 based on grid information and/or computational (e.g., power) demands of the datacenter regions 330-1, 330-2, 330-3.

For example, the micro-grid controller 338 receives a datacenter region balance information from each of the datacenter regions 330-1, 330-2, 330-3 of the micro-grid 332. The datacenter region balance information includes both an amount of micro-plant electrical power generated by the micro-plant 336-1, 336-2, 336-3 local to that datacenter region 330-1, 330-2, 330-3 and the power demand of that datacenter region 330-1, 330-2, 330-3, such as the co-location power demand of the co-locations therein. In some embodiments, the datacenter region balance information further includes the amount of grid electrical power received by the datacenter region 330-1, 330-2, 330-3. The micro-grid controller 338 can, thereby, distribute the available micro-grid electrical power within the micro-grid 332 to provide sufficient power to each datacenter region 330-1, 330-2, 330-3 and in the desired ratio of on-site electrical power (micro-plant electrical power) and grid electrical power based at least partially on grid information.

In some embodiments, the grid information includes grid pricing information and/or grid source information or grid carbon load information. In some embodiments, the micro-grid controller 338 is in data communication with the micro-plants 336-1, 336-2, 336-3 to adjust the output of the micro-reactors and/or the conversion generators for exportation of electricity from through the micro-grid 332 and/or to the regional power grid 308. For example, the micro-grid controller 338 may instruct the micro-plants 336-1, 336-2, 336-3 to change electricity production based upon grid pricing received from the regional power grid 308. In some examples, the micro-grid controller 338 may anticipate (based on historical information or identified trends of associated metrics) a grid pricing, and the micro-grid controller 338 may instruct the micro-plants 336-1, 336-2, 336-3 to store thermal energy and/or electricity for discharge during the period of anticipated grid pricing.

In another example, the micro-grid controller 338 may instruct the micro-plants 336-1, 336-2, 336-3 to change electricity production based upon grid source information (i.e., coal energy versus wind energy) received from the regional power grid 308. In some examples, the micro-grid controller 338 may anticipate (based on historical information or identified trends of associated metrics) a grid source, and the micro-grid controller 338 may instruct the micro-plants 336-1, 336-2, 336-3 to store thermal energy and/or electricity for discharge during the period of an anticipated grid source.

For example, the micro-grid controller 338 adjusts the electricity output of the micro-grid 332 and/or energy storage of the micro-grid 332 based at least partially on the carbon load of the grid sources or anticipated grid sources. In some examples, the micro-grid controller 338 adjusts the electricity output of the micro-grid 332 and/or energy storage of the micro-grid 332 to reduce or minimize the carbon load of the electricity consumed by the datacenter power system 300. In some examples, the adjusts the electricity output of the micro-grid 332 and/or energy storage of the micro-grid 332 to limit and/or prevent adverse effects on the datacenter power system 300 from intermittent or variable regional power supply. For example, some renewable energy sources, while reducing a carbon load of the energy production, vary with the weather (e.g., cloud cover, temperature, wind speed) and other conditions. In such examples, stored energy (thermal or electrical) in the micro-grid can allow the micro-grid to compensate for variations in the regional power grid 308. In other examples, a failure of a grid connection 310-1, 310-2, 310-3 or the regional power grid 308 can be detected by the micro-grid controller 338 and compensated for by the micro-grid 332.

FIG. 4 is a diagram of an embodiment of a datacenter power system 400 including a micro-grid 432 that is independent of a regional power grid. In some embodiments, a micro-grid 432 has a maximum output greater than the maximum electrical demand of the datacenter (i.e., the combined electrical demand of the datacenter regions 430-1, 430-2, 430-3). In some embodiments, each micro-plant 436-1, 436-2, 436-3 of the micro-grid 432 has an electrical capacity at least 20% greater than the electrical demand of the associated datacenter region 430-1, 430-2, 430-3. In some embodiments, each micro-plant 436-1, 436-2, 436-3 of the micro-grid 432 has an electrical capacity such that the micro-grid 432 can supply electricity to all datacenter regions 430-1, 430-2, 430-3 under a maximum computational load with at least one of the micro-plants offline. For example, during maintenance and/or a failure of the first micro-plant 436-1 or a portion of the first micro-plant 436-1, the second micro-plant 436-2 and the third micro-plant 436-3 have a combined electrical output equal to or greater than the maximum electrical demand of the three datacenter regions 430-1, 430-2, 430-3. In some embodiments, the micro-grid 432, as a whole, has a total electrical output capacity sufficient to supply electricity to all datacenter regions 430-1, 430-2, 430-3 under a maximum computational load with at least one of the micro-plants offline. For example, the micro-grid 432 may include thermal stores and/or electrical stores that allow the electrical output capacity of the micro-grid 432 to be, at least temporarily, greater than the maximum output of the micro-reactors alone in the micro-grid 432.

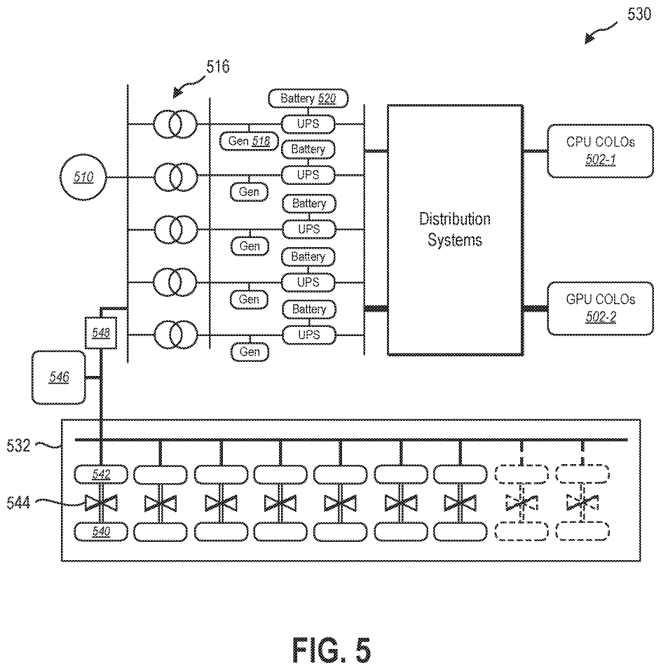

FIG. 5 is a schematic flow diagram of an embodiment of a datacenter (or datacenter region 530) at least partially powered by a micro-plant 532 including a plurality of micro-reactors 540 and conversion generators 542. In some examples, a micro-reactor generates no more than 20 Megawatts (MW) of power. In some examples, the micro-reactor 540 generates thermal energy, and a turbine or other conversion generator 542 converts the thermal energy to electricity. In some examples, the micro-reactor 540 is a nuclear micro-reactor. In some example, the micro-reactor 540 is a combustion reactor. In some examples, the micro-reactor 540 is a nuclear fission reactor. In some examples, the micro-reactor 540 is a nuclear fusion reactor. In some embodiments, the conversion generator 542 is a steam turbine generator.

The micro-plant 532 includes, in some embodiments, thermal valves 544 that selectively limit the movement of thermal energy from the micro-reactors 540 to the conversion generators 542. For example, the thermal valves 544 may limit or prevent the flow of steam from the micro-reactor 540 to the conversion generator 542. In some embodiments, the thermal valves 544 limit or prevent the flow of a liquid medium from the micro-reactor 540 to the conversion generator 542.

In some embodiments, the micro-plant 532 includes a conversion generator 542 for each of the micro-reactors 540. In some examples, the micro-plant 532 includes a single conversion generator 542 for each micro-reactor 540 such as a 1:1 ratio of conversion generators 542 to micro-reactors 540. In some examples, the micro-plant 532 includes at least one conversion generator 542 for each micro-reactor 540. In some examples, the micro-plant 532 includes more conversion generators 542 than micro-reactors 540. In some embodiments, at least one of the micro-reactors 540 is directly coupled to a unique conversion generator 542. In some embodiments, each of the micro-reactors 540 is directly coupled to an individual conversion generator 542.

In some embodiments, the micro-plant 532 provides electricity from the micro-plant 532 to power co-locations 502-1, 502-2 of the datacenter region 530. In some embodiments, the micro-plant 532 provides electricity to an energy storage system (ESS) such as an electrical store 546 for later use by the co-locations 502-1, 502-2. For example, the power demands of the co-locations 502-1, 502-2 can change nearly instantaneous with compute demands, and the micro-reactors 540 and/or conversion generators 542 may have a delay before the micro-plant 532 can change electrical output to match the power demands of the co-locations 502-1, 502-2.

In some embodiments, an electrical store 546, such as a chemical battery ESS, can provide load following as the power demands (i.e., load) changes in the datacenter region 530. In some embodiments, the electrical store 546 is located between or parallel to the electrical connection between the micro-plant 532 and a low-voltage transformer 516 of the datacenter region 530. For example, the micro-plant 532 and the electrical store 546 provide electrical power at a medium voltage. In other examples, the micro-plant 532 and the electrical store 546 provide electrical power at a high voltage. In some embodiments, the micro-plant 532 and the electrical store 546 provide electrical power to the datacenter region 530 at different voltages. For example, the micro-plant 532 may provide electrical power at a high voltage to the datacenter region 530 and to the electrical store 546, while the electrical store 546 is configured to discharge at a medium voltage or low voltage.

In some embodiments, the micro-plant 532 provides electrical power to the datacenter region 530 at the same high voltage as the grid connection 510. For example, the micro-plant 532 provides micro-plant electrical power at the high voltage of the grid electrical power proximate to the grid connection 510. In such examples, the datacenter power system may receive and handle the micro-plant electrical power the same as the grid electrical power. In some embodiments, the micro-plant 532 provides electrical power to the datacenter region 530 at a lower voltage than the grid connection 510. In some embodiments, the electrical power from the micro-plant 532 is converted by at least one transformer 516 to a low voltage. In some embodiments, the datacenter region 530 further includes additional supplemental power sources or supplies at the low voltage to power the co-locations 502-1, 502-2, such as a generator 518 and/or battery storage devices 520. In some examples, the additional power sources or storage devices, such as the generator 518 and/or battery storage devices 520 provide electrical power at the medium voltage.

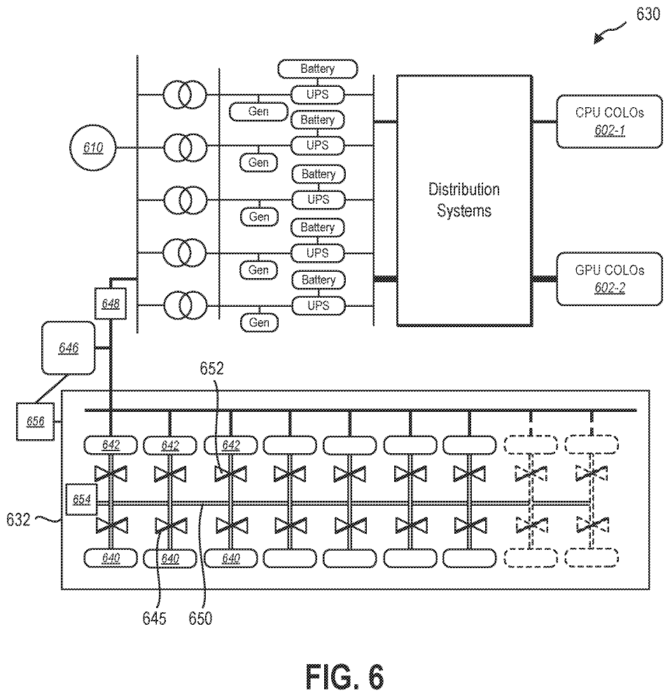

FIG. 6 is a schematic flow diagram of an embodiment of a datacenter (or datacenter region 630) at least partially powered by a micro-plant 632 including a plurality of micro-reactors 640 with a thermal manifold 650 distributing the thermal energy to a plurality of conversion generators 642. In some embodiments, the micro-plant has a thermal manifold 650 or thermal bus that receives thermal energy from a plurality of micro-reactors 640. In some examples, the thermal manifold 650 receives thermal energy from the plurality of micro-reactors 640 and distributes the thermal energy to one or more conversion generators 642. In some examples, the thermal manifold 650 receives thermal energy from the plurality of micro-reactors 640 and distributes the thermal energy to a plurality of conversion generators 642 that includes at least one conversion generator 642 for each micro-reactor 640. In some examples, the thermal manifold 650 receives thermal energy from the plurality of micro-reactors 640 and distributes the thermal energy to a plurality of conversion generators 642 that includes a greater quantity of conversion generators 642 than micro-reactors 640 in the plurality of micro-reactors 640.

In some embodiments, the micro-plant 632 includes a plurality of thermal valves to control, limit, and direct the flow of thermal energy from the micro-reactors 640 to the conversion generators 642. For example, in some embodiments, the micro-plant 632 includes one or more reactor thermal valves 645 positioned between a micro-reactor 640 and the thermal manifold 650 to control or limit the flow of thermal energy therebetween. In some embodiments, at least one micro-reactor 640 has an associated reactor thermal valve 645 between the micro-reactor 640 and the thermal manifold 650. In some embodiments, each micro-reactor 640 has an associated reactor thermal valve 645 between the micro-reactor 640 and the thermal manifold 650.

Once received at the thermal manifold 650, the thermal energy is able to move through the thermal manifold to one or more conversion generators 642. In some embodiments, the micro-plant 632 includes one or more generator thermal valves 652 positioned between the thermal manifold 650 and a conversion generator 642 to control or limit the flow of thermal energy therebetween. In some embodiments, at least one conversion generator 642 has an associated generator thermal valves 652 between the conversion generator 642 and the thermal manifold 650. In some embodiments, each conversion generator 642 has an associated generator thermal valves 652 between the conversion generator 642 and the thermal manifold 650.

In some embodiments, the micro-plant 632 has both reactor thermal valves 645 and generator thermal valve 652, which allows the selective routing of thermal energy through the thermal manifold. For example, the micro-plant 632 may generate thermal energy from less micro-reactors 640 than the quantity of conversion generators 642 converting the thermal energy to electricity in a particular moment. In other examples, the micro-plant 632 may generate thermal energy from move micro-reactors 640 than the quantity of conversion generators 642 converting the thermal energy to electricity in a particular moment. In some examples, selective routing of thermal energy can allow maintenance or repairs on portions of the micro-plant 632. In some examples, the micro-plant 632 may adjust the efficiency of the electricity output by changing a ratio of active micro-reactors 640 to active conversion generators 642. In some embodiments, internal losses of a conversion generator 642 makes the micro-plant 632 more efficient when micro-reactors 640 provide thermal energy to a single conversion generator 642. For example, start up and shut down of a micro-reactor may be energy inefficient, and idling the micro-reactor at a low reactivity may be more energy efficient when thermal energy from a plurality of low reactivity micro-reactors provide thermal energy to a single conversion generator.

In some embodiments, excess thermal energy is directed to a thermal ESS, such as a thermal store 654 in the micro-plant 632 or connected to the micro-plant 632. For example, the thermal manifold 650 is in thermal communication with a thermal store 654. In some embodiments, the thermal store 654 may include a thermal mass that receives and retains the thermal energy for subsequent distribution to one or more conversion generators 642. In some embodiments, the thermal mass is sand. In some embodiments, the thermal mass is water. In some embodiments, the thermal mass is a metal or metal alloy. The thermal store 654 may distribute the stored thermal energy back to the thermal manifold 650 for conversion to electricity through one or more of the conversion generators 642. In some embodiments, a conversion generator 642 is connected directly to the thermal store 654 for conversion of the stored thermal energy.

A micro-plant controller 656, in some embodiments, is in data communication with the components of the micro-plant 632 to adjust the electricity output of the micro-plant 632. In some embodiments, the micro-plant controller 656 controls the thermal output of the micro-reactors 640. For example, the micro-plant controller 656 adjusts the fuel delivery of the micro-reactor(s) 640 of the micro-plant. For example, the micro-plant controller 656 adjusts the combustion rate of the micro-reactor(s) 640 of the micro-plant 632. For example, the micro-plant controller 656 adjusts the rate of fission or reactivity, such as with control material, of the micro-reactor(s) 640 of the micro-plant 632.

In some embodiments, the micro-plant controller 656 controls one or more thermal valves 645, 652 between the micro-reactors 640 and the conversion generator 642. In some embodiments, the micro-plant controller 656 selectively routes at least a portion of the thermal energy to the thermal energy store 654 for later conversion to electricity.

In some embodiments, the micro-plant controller 656 controls the electricity distribution after the conversion generators 642. In some embodiments, the micro-plant controller 656 directs at least a portion in the electricity generated by the conversion generator(s) 642 to a power distribution system of the datacenter for use in co-locations 602-1, 602-2 or other components of the datacenter region 630. In some embodiments, the micro-plant controller 656 directs at least a portion of the electricity generated by the conversion generator(s) 642 to an electricity store 646, such as a battery. In some embodiments, the micro-plant controller 656 directs at least a portion in the electricity generated by the conversion generator(s) 642 to a grid connection 610 for exportation to the regional power grid. In some embodiments, at least a portion of the electricity is directed to another micro-plant or another datacenter region within a micro-grid (such as described in relation to FIG. 3 and FIG. 4) including a plurality of micro-plants.

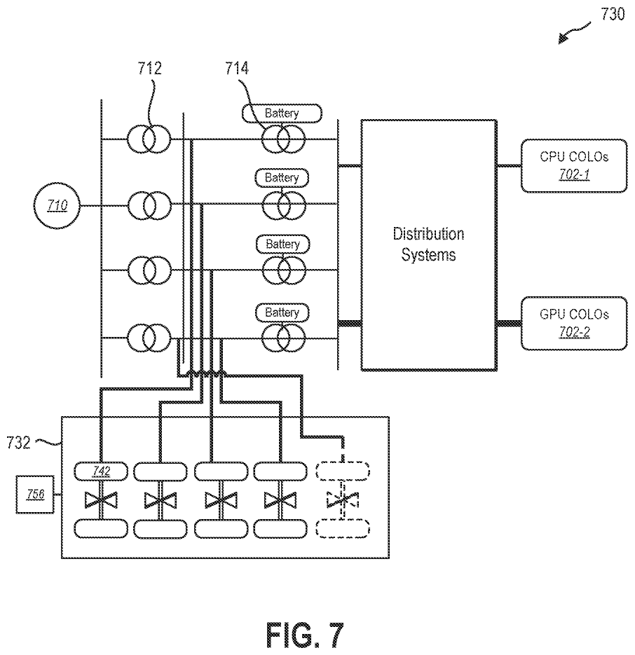

FIG. 7 is a schematic representation of another embodiment of a datacenter region 730 with a micro-plant 732 that generates electricity at a medium voltage or provides high voltage electricity through a transformer to the medium voltage bus of the datacenter region 730. As described herein, in some embodiments, the micro-plant 732 outputs at least a portion of the electrical power generated by the conversion generators 742 at a medium voltage to the datacenter region 730 before the medium voltage transformer(s) 714. In some embodiments, the micro-plant 732 outputs at least a portion of the micro-plant electrical power generated by the conversion generators 742 at a medium voltage to the datacenter region opposite a high voltage transformer 712 from the grid connection 710. In some embodiments, the electricity produced by the micro-plant 732 has a shorter distance to travel than the electricity received through the grid connection 710. Therefore, the electricity can be transmitted at a lower voltage than the high-voltage electricity of the regional grid. By delivering the electrical output of the micro-plant 732 at a lower voltage, one or more transformers can be skipped, such as the high voltage transformers 712.

In some embodiments, the medium voltage transformer 714 and/or the low voltage transformer 716 is a solid-state transformer. A powered solid-state transformer, in some embodiments, can change voltage and frequency of the input electricity to facilitate the incorporation of output electricity from the micro-plant 732 into an integrated power system.

In some embodiments, the medium voltage transformers 714 are connected to a plurality of electrical conduits, and the micro-plant 732 outputs to the plurality of electrical conduits. In some embodiments, the micro-plant 732 is configured to provide different amounts of electricity to the different electrical conduits based at least partially on the power demand of the co-locations associated with each of the electrical conduits. In at least one example, the electricity output of the micro-plant 732 is directed to different electrical conduits and/or at different voltages by a micro-plant controller 756 (e.g., a micro-plant controller 656 described in relation to FIG. 6).

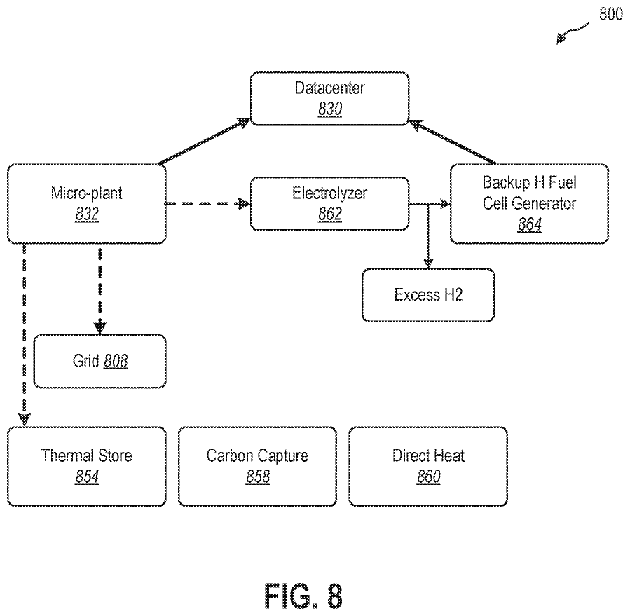

FIG. 8 is a schematic representation of a micro-reactor or micro-plant 832 of micro-reactors within an embodiment of a datacenter power system 800. In some embodiments, the micro-plant 832 generates thermal energy (heat) and converts at least a portion of that thermal energy to electricity. The micro-plant 832 distributes at least a portion of the output electricity to the datacenter or datacenter region 830 to power co-locations and other resources of the datacenter. In some embodiments, the micro-plant 832 further produces excess electricity and/or excess heat that is beyond the demands of the datacenter or datacenter region 830.

In some embodiments, the excess heat or thermal energy is exported to a thermal store 854, as described in relation to FIG. 6, for later conversion to electricity. In some embodiments, the excess heat is exported for carbon capture 858 and/or sequestration to further lower the carbon load of the datacenter power system 800. In some embodiments, the excess heat is exported for local structural heating, such as for structural heating of residential homes or commercial buildings (e.g., district heat 860).

In some embodiments, the micro-plant 832 produces excess electricity. In some embodiments, the excess electricity is exported to the regional power grid 808, such as described in relation to FIG. 3. In some embodiments, a micro-grid controller receives grid information and, based at least partially on the grid information, exports excess electricity to the regional power grid. In some embodiments, the micro-plant 832 delivers excess electricity to other power sources of the datacenter power system 800. For example, the excess electricity may be distributed to a chemical ESS. In some embodiments, the excess electricity powers an electrolyzer 862 to produce hydrogen feedstock for a hydrogen fuel cell generator 864 where the energy is stored in the chemical energy of the hydrogen feedstock.

In at least some embodiments, a datacenter powered by a micro-reactor and/or micro-plant generates thermal energy and electricity that can power at least a portion of the datacenter as well as be exported for additional uses.

### INDUSTRIAL APPLICABILITY

The present disclosure generally relates to systems and methods for providing electrical power to a datacenter. Conventional datacenters rely on regional power grids to supply electricity to the datacenter. A reliance on regional power grid can leave the datacenter susceptible to failures of the regional power grid, variations in demand on the power grid, variations in the supply to the power grid, variations to the carbon load of the regional power grid, and other properties of the regional power grid that out of the control of the designers or operators of the datacenter. On-site power generation allows the datacenter to limit or eliminate dependency on the regional power grid and even allow the datacenter to export power to the regional power grid. In some embodiments, power distribution efficiency is increased by having on-site power generation by limiting the distance the electricity is transported to or within the datacenter. In some embodiments, power generation efficiency is increased by generating power based on the current or anticipated power demands of the datacenter. In at least one embodiment, on-site power generation allows a datacenter to operate without a grid connection to a regional power grid.

In some embodiments, a datacenter power system according to the present disclosure includes at least one micro-reactor plant (“micro-plant”) including a plurality of micro-reactors. In some examples, a micro-reactor generates no more than 2 Megawatts (MW) of power. In some examples, the micro-reactor generates thermal energy, and a turbine or other conversion generator converts the thermal energy to electricity. In some examples, the micro-reactor is a nuclear micro-reactor. In some example, the micro-reactor is a combustion reactor. In some examples, the micro-reactor is a nuclear fission reactor. In some examples, the micro-reactor is a nuclear fusion reactor.

In some embodiments, the micro-plant includes a conversion generator for each of the micro-reactors. In some examples, the micro-plant includes a single conversion generator for each micro-reactor such as a 1:1 ratio of conversion generators to micro-reactors. In some examples, the micro-plant includes at least one conversion generator for each micro-reactor. In some examples, the micro-plant includes more conversion generators than micro-reactors. In some embodiments, at least one of the micro-reactors is directly coupled to a unique conversion generator. In some embodiments, each of the micro-reactors is directly coupled to an individual conversion generator. In some embodiments, the micro-plant has a thermal manifold or thermal bus that receives thermal energy from a plurality of micro-reactors. In some examples, the thermal manifold receives thermal energy from the plurality of micro-reactors and distributes the thermal energy to one or more conversion generators. In some examples, the thermal manifold receives thermal energy from the plurality of micro-reactors and distributes the thermal energy to a plurality of conversion generators that includes at least one conversion generator for each micro-reactor. In some examples, the thermal manifold receives thermal energy from the plurality of micro-reactors and distributes the thermal energy to a plurality of conversion generators that includes a greater quantity of conversion generators than micro-reactors in the plurality of micro-reactors.

In some embodiments, the micro-plant includes valves to selectively limit and/or control the transfer of heat from the plurality of micro-reactors to the plurality of conversion generators. For example, a micro-reactor heats a fluid with thermal energy, and the fluid carries the thermal energy to the conversion generator to convert the thermal energy to electricity. In some examples, one or more thermal valves between the micro-reactor and the conversion generator can control the amount of fluid and/or thermal energy is delivered to the conversion generator. In some examples, one or more micro-reactor thermal valves limits or prevents fluid and/or thermal energy from moving from the micro-reactor(s) to the thermal manifold before the conversion generator(s). In some examples, one or more generator thermal valves limits or prevents fluid and/or thermal energy from moving from the thermal manifold to the conversion generator(s). In some examples, a combination of micro-reactor thermal valves and generator thermal valves can selectively route the fluid and/or thermal energy from one or more micro-reactors of the plurality of micro-reactors to one or more conversion generators of the plurality of conversion generators.

The micro-plant has a micro-plant controller configured to adjust the electricity output of the micro-plant. In some embodiments, the micro-plant controller controls the thermal output of the micro-reactors. For example, the micro-plant controller adjusts the fuel delivery of the micro-reactor(s) of the micro-plant. For example, the micro-plant controller adjusts the combustion rate of the micro-reactor(s) of the micro-plant. For example, the micro-plant controller adjusts the rate of fission or reactivity, such as with control material, of the micro-reactor(s) of the micro-plant.

In some embodiments, the micro-plant controller controls one or more thermal valves between the micro-reactors and the conversion generator. As described above, the thermal valves can selectively route or limit the movement of fluid and/or thermal energy from the micro-reactor(s) to the conversion generator(s) of the micro-plant. In some embodiments, the micro-plant controller selectively routes at least a portion of the thermal energy to a thermal energy store for later conversion to electricity.

In some embodiments, the micro-plant controller controls the electricity distribution after the conversion generators. In some embodiments, the micro-plant controller directs at least a portion in the electricity generated by the conversion generator(s) to a power distribution system of the datacenter. In some embodiments, the micro-plant controller directs at least a portion of the electricity generated by the conversion system to an electricity store, such as a battery. In some embodiments, the micro-plant controller directs at least a portion in the electricity generated by the conversion generator(s) to a grid connection for exportation to the regional power grid. In some embodiments, at least a portion of the electricity is directed to another micro-plant or another datacenter region within a micro-grid including a plurality of micro-plants.

The datacenter power system provides electrical power to, among other portions of the datacenter, one or more co-locations. The co-locations include a plurality of computing devices. In some examples, the co-location includes a power supply unit (PSU) that receives, converts, and distributes electrical power to the computing devices.

The datacenter power system, in some examples, receives grid electrical power from a regional utility grid. The regional utility grid provides the grid electrical power at a higher voltage than the co-location can utilize, and the datacenter power system converts the grid electrical power for use in the co-locations of the datacenter. For example, the datacenter power system receives the grid electrical power through a grid connection to a high voltage transformer that steps the voltage down. In some examples, the datacenter power system then includes a medium voltage transformer and a low voltage transformer to further step the voltage down in stages and the amperage of the electrical current increases with each step down of voltage. The electrical conduits and the datacenter power system, as a whole, must compensate for the increased amperage.

For example, as the amperage through a resistive electrical conduit (e.g., copper wire or cable) increases, the resistivity of the resistive electrical conduit converts a portion of the electrical power to heat and other loss mechanisms. The electrical loss and heat generation are undesirable in the datacenter power system. In some examples, the datacenter power system may include additional power sources or storage devices, such as a generator and/or battery storage devices. In some examples, the additional power sources or storage devices, such as the generator and/or battery storage devices, are coupled to the datacenter power system at different stages of the voltage depending on the provided voltage of the additional power sources or storage devices.

In some embodiments, the datacenter power system receives a high voltage grid electrical power through the grid connection to the high voltage transformer. The incoming grid electrical power is received with a grid voltage, a grid amperage, and a grid frequency. In some examples, the grid voltage is a high voltage no less than 110 kilovolts (kV). In some examples, the grid voltage is an extra-high voltage no less than 345 kV. In some examples, the grid voltage is an ultra-high voltage no less than 1100 kV. Stepping down the grid voltage can produce high amperage, as the voltage and amperage are inversely proportional for a given power (Wattage), assuming limited or no losses during conversion.

For example, stepping down the grid voltage of the grid electrical power through the high voltage transformer to a medium voltage electrical power having a medium voltage ten times less than the grid voltage results in a medium amperage ten times greater than the grid amperage. Further step-downs of the medium voltage electrical power to a low voltage electrical power through the medium voltage transformer, and of the low voltage electrical power to a co-location electrical power usable by the co-location through the low voltage transformer can continue increasing the amperage by orders of magnitude. As datacenters commonly consume electrical power on the order of Megawatts, the amperage needs to be managed at each step-down in a conventional datacenter power system to avoid excessive electrical losses and heat generation. In some embodiments, on-site power generation eliminates the need to transmit electricity over long distances, and on-site power generation can provide power a lower voltage than a regional power grid, reducing the need for conversion and managing changes in amperage.

In some embodiments, a datacenter power system includes a plurality of datacenter regions. In some embodiments, each of the datacenter regions include at least some of the elements described herein. For example, the datacenter regions each have at least one grid connection through which each of the datacenter regions receive high voltage electrical power from the regional power grid.

In some embodiments, the datacenter regions are in data communication with one another to allow computing allocations and load management between the datacenter regions. However, each of the datacenter regions is independently powered by grid connections, and each datacenter region is dependent on the stability, availability, and cost of the regional power grid.

In some embodiments, a micro-grid has electrical conduits that communicate electrical power between datacenter regions. In some embodiments, each datacenter region has a micro-plant local to the datacenter region that generates micro-plant electrical power, and each datacenter region has a grid connection to a regional power grid to receive grid electrical power.

The datacenter power system, therefore, has redundancy in power generation from the regional power grid through the grid connections and from the micro-grid through the electrical conduits. In some embodiments, a micro-grid controller balances the electrical power delivery between the micro-plants through the micro-grid and from the grid connections based on grid information and/or computational (e.g., power) demands of the datacenter regions.

For example, the micro-grid controller receives a datacenter region balance information from each of the datacenter regions of the micro-grid. The datacenter region balance information includes both an amount of micro-plant electrical power generated by the micro-plant local to that datacenter region and the power demand of that datacenter region, such as the co-location power demand of the co-locations therein. In some embodiments, the datacenter region balance information further includes the amount of grid electrical power received by the datacenter region. The micro-grid controller can, thereby, distribute the available micro-grid electrical power within the micro-grid to provide sufficient power to each datacenter region and in the desired ratio of on-site electrical power (micro-plant electrical power) and grid electrical power based at least partially on grid information.

In some embodiments, the grid information includes grid pricing information and/or grid source information or grid carbon load information. In some embodiments, the micro-grid controller is in data communication with the micro-plants to adjust the output of the micro-reactors and/or the conversion generators for exportation of electricity from through the micro-grid and/or to the regional power grid. For example, the micro-grid controller may instruct the micro-plants to change electricity production based upon grid pricing received from the regional power grid. In some examples, the micro-grid controller may anticipate (based on historical information or identified trends of associated metrics) a grid pricing, and the micro-grid controller may instruct the micro-plants to store thermal energy and/or electricity for discharge during the period of anticipated grid pricing.

In another example, the micro-grid controller may instruct the micro-plants to change electricity production based upon grid source information (i.e., coal energy versus wind energy) received from the regional power grid. In some examples, the micro-grid controller may anticipate (based on historical information or identified trends of associated metrics) a grid source, and the micro-grid controller may instruct the micro-plants to store thermal energy and/or electricity for discharge during the period of an anticipated grid source.

For example, the micro-grid controller adjusts the electricity output of the micro-grid and/or energy storage of the micro-grid based at least partially on the carbon load of the grid sources or anticipated grid sources. In some examples, the micro-grid controller adjusts the electricity output of the micro-grid and/or energy storage of the micro-grid to reduce or minimize the carbon load of the electricity consumed by the datacenter power system. In some examples, the adjusts the electricity output of the micro-grid and/or energy storage of the micro-grid to limit and/or prevent adverse effects on the datacenter power system from intermittent or variable regional power supply. For example, some renewable energy sources, while reducing a carbon load of the energy production, vary with the weather (e.g., cloud cover, temperature, wind speed) and other conditions. In such examples, stored energy (thermal or electrical) in the micro-grid can allow the micro-grid to compensate for variations in the regional power grid. In other examples, a failure of a grid connection or the regional power grid can be detected by the micro-grid controller and compensated for by the micro-grid.

In some embodiments, a datacenter power system including a micro-grid is independent of a regional power grid. In some embodiments, a micro-grid has a maximum output greater than the maximum electrical demand of the datacenter (i.e., the combined electrical demand of the datacenter regions). In some embodiments, each micro-plant of the micro-grid has an electrical capacity at least 20% greater than the electrical demand of the associated datacenter region. In some embodiments, each micro-plant of the micro-grid has an electrical capacity such that the micro-grid can supply electricity to all datacenter regions under a maximum computational load with at least one of the micro-plants offline. For example, during maintenance and/or a failure of the first micro-plant or a portion of the first micro-plant, the second micro-plant and the third micro-plant have a combined electrical output equal to or greater than the maximum electrical demand of the three datacenter regions. In some embodiments, the micro-grid, as a whole, has a total electrical output capacity sufficient to supply electricity to all datacenter regions under a maximum computational load with at least one of the micro-plants offline. For example, the micro-grid may include thermal stores and/or electrical stores that allow the electrical output capacity of the micro-grid to be, at least temporarily, greater than the maximum output of the micro-reactors alone in the micro-grid.

In some embodiments, a datacenter (or datacenter region) is at least partially powered by a micro-plant including a plurality of micro-reactors and conversion generators. In some examples, a micro-reactor generates no more than 2 Megawatts (MW) of power. In some examples, the micro-reactor generates thermal energy, and a turbine or other conversion generator converts the thermal energy to electricity. In some examples, the micro-reactor is a nuclear micro-reactor. In some example, the micro-reactor is a combustion reactor. In some examples, the micro-reactor is a nuclear fission reactor. In some examples, the micro-reactor is a nuclear fusion reactor. In some embodiments, the conversion generator is a steam turbine generator.

The micro-plant includes, in some embodiments, thermal valves that selectively limit the movement of thermal energy from the micro-reactors to the conversion generators. For example, the thermal valves may limit or prevent the flow of steam from the micro-reactor to the conversion generator. In some embodiments, the thermal valves limit or prevent the flow of a liquid medium from the micro-reactor to the conversion generator.

In some embodiments, the micro-plant includes a conversion generator for each of the micro-reactors. In some examples, the micro-plant includes a single conversion generator for each micro-reactor such as a 1:1 ratio of conversion generators to micro-reactors. In some examples, the micro-plant includes at least one conversion generator for each micro-reactor. In some examples, the micro-plant includes more conversion generators than micro-reactors. In some embodiments, at least one of the micro-reactors is directly coupled to a unique conversion generator. In some embodiments, each of the micro-reactors is directly coupled to an individual conversion generator.

In some embodiments, the micro-plant provides electricity from the micro-plant to power co-locations of the datacenter region. In some embodiments, the micro-plant provides electricity to an electrical store for later use by the co-locations. For example, the power demands of the co-locations can change nearly instantaneous with compute demands, and the micro-reactors and/or conversion generators may have a delay before the micro-plant can change electrical output to match the power demands of the co-locations.

In some embodiments, an electrical store, such as a battery, can provide load following as the power demands (i.e., load) changes in the datacenter region. In some embodiments, the electrical store is located between or parallel to the electrical connection between the micro-plant and a low-voltage transformer of the datacenter region. For example, the micro-plant and the electrical store provide electrical power at a medium voltage. In other examples, the micro-plant and the electrical store provide electrical power at a high voltage. In some embodiments, the micro-plant and the electrical store provide electrical power to the datacenter region at different voltages. For example, the micro-plant may provide electrical power at a high voltage to the datacenter region and to the electrical store, while the electrical store is configured to discharge at a medium voltage or low voltage.

In some embodiments, the micro-plant provides electrical power to the datacenter region at the same high voltage as the grid connection. For example, the micro-plant provides micro-plant electrical power at the high voltage of the grid electrical power proximate to the grid connection. In such examples, the datacenter power system may receive and handle the micro-plant electrical power the same as the grid electrical power. In some embodiments, the micro-plant provides electrical power to the datacenter region at a lower voltage than the grid connection. In some embodiments, the electrical power from the micro-plant is converted by at least one transformer to a low voltage. In some embodiments, the datacenter region further includes additional supplemental power sources or supplies at the low voltage to power the co-locations, such as a generator and/or battery storage devices. In some examples, the additional power sources or storage devices, such as the generator and/or battery storage devices provide electrical power at a medium voltage.

In some embodiments, the micro-plant has a thermal manifold or thermal bus that receives thermal energy from a plurality of micro-reactors. In some examples, the thermal manifold receives thermal energy from the plurality of micro-reactors and distributes the thermal energy to one or more conversion generators. In some examples, the thermal manifold receives thermal energy from the plurality of micro-reactors and distributes the thermal energy to a plurality of conversion generators that includes at least one conversion generator for each micro-reactor. In some examples, the thermal manifold receives thermal energy from the plurality of micro-reactors and distributes the thermal energy to a plurality of conversion generators that includes a greater quantity of conversion generators than micro-reactors in the plurality of micro-reactors.

In some embodiments, the micro-plant includes a plurality of thermal valves to control, limit, and direct the flow of thermal energy from the micro-reactors to the conversion generators. For example, in some embodiments, the micro-plant includes one or more reactor thermal valves positioned between a micro-reactor and the thermal manifold to control or limit the flow of thermal energy therebetween. In some embodiments, at least one micro-reactor has an associated reactor thermal valve between the micro-reactor and the thermal manifold. In some embodiments, each micro-reactor has an associated reactor thermal valve between the micro-reactor and the thermal manifold.

Once received at the thermal manifold, the thermal energy is able to move through the thermal manifold to one or more conversion generators. In some embodiments, the micro-plant includes one or more generator thermal valves positioned between the thermal manifold and a conversion generator to control or limit the flow of thermal energy therebetween. In some embodiments, at least one conversion generator has an associated generator thermal valves between the conversion generator and the thermal manifold. In some embodiments, each conversion generator has an associated generator thermal valves between the conversion generator and the thermal manifold.

In some embodiments, the micro-plant has both reactor thermal valves and generator thermal valve, which allows the selective routing of thermal energy through the thermal manifold. For example, the micro-plant may generate thermal energy from less micro-reactors than the quantity of conversion generators converting the thermal energy to electricity in a particular moment. In other examples, the micro-plant may generate thermal energy from move micro-reactors than the quantity of conversion generators converting the thermal energy to electricity in a particular moment. In some examples, selective routing of thermal energy can allow maintenance or repairs on portions of the micro-plant. In some examples, the micro-plant may adjust the efficiency of the electricity output by changing a ratio of active micro-reactors to active conversion generators. In some embodiments, internal losses of a conversion generator makes the micro-plant more efficient when micro-reactors provide thermal energy to a single conversion generator. For example, start up and shut down of a micro-reactor may be energy inefficient, and idling the micro-reactor at a low reactivity may be more energy efficient when thermal energy from a plurality of low reactivity micro-reactors provide thermal energy to a single conversion generator.

In some embodiments, excess thermal energy is directed to a thermal ESS, such as a thermal store, in the micro-plant or connected to the micro-plant. For example, the thermal manifold is in thermal communication with a thermal store. In some embodiments, the thermal store may include a thermal mass that receives and retains the thermal energy for subsequent distribution to one or more conversion generators. In some embodiments, the thermal mass is sand. In some embodiments, the thermal mass is water. In some embodiments, the thermal mass is a metal or metal alloy. The thermal store may distribute the stored thermal energy back to the thermal manifold for conversion to electricity through one or more of the conversion generators. In some embodiments, a conversion generator is connected directly to the thermal store for conversion of the stored thermal energy.

A micro-plant controller, in some embodiments, is in data communication with the components of the micro-plant to adjust the electricity output of the micro-plant. In some embodiments, the micro-plant controller controls the thermal output of the micro-reactors. For example, the micro-plant controller adjusts the fuel delivery of the micro-reactor(s) of the micro-plant. For example, the micro-plant controller adjusts the combustion rate of the micro-reactor(s) of the micro-plant. For example, the micro-plant controller adjusts the rate of fission or reactivity, such as with control material, of the micro-reactor(s) of the micro-plant.

In some embodiments, the micro-plant controller controls one or more thermal valves between the micro-reactors and the conversion generator. In some embodiments, the micro-plant controller selectively routes at least a portion of the thermal energy to the thermal energy store for later conversion to electricity.

In some embodiments, the micro-plant controller controls the electricity distribution after the conversion generators. In some embodiments, the micro-plant controller directs at least a portion in the electricity generated by the conversion generator(s) to a power distribution system of the datacenter for use in co-locations or other components of the datacenter region. In some embodiments, the micro-plant controller directs at least a portion of the electricity generated by the conversion generator(s) to an electricity store, such as a battery. In some embodiments, the micro-plant controller directs at least a portion in the electricity generated by the conversion generator(s) to a grid connection for exportation to the regional power grid. In some embodiments, at least a portion of the electricity is directed to another micro-plant or another datacenter region within a micro-grid including a plurality of micro-plants.

As described herein, in some embodiments, the micro-plant outputs at least a portion of the electrical power generated by the conversion generators at a medium voltage to the datacenter region before the low voltage transformer(s). In some embodiments, the micro-plant outputs at least a portion of the electrical power generated by the conversion generators at a medium voltage to the datacenter region opposite a high voltage transformer from the grid connection. In some embodiments, the electricity produced by the micro-plant has a shorter distance to travel than the electricity received through the grid connection. Therefore, the electricity can be transmitted at a lower voltage than the high-voltage electricity of the regional grid. By delivering the electrical output of the micro-plant at a lower voltage, one or more transformers can be skipped, such as the medium voltage transformers.

In some embodiments, the medium voltage transformer and/or the low voltage transformer is a solid-state transformer. A powered solid-state transformer, in some embodiments, can change voltage and frequency of the input electricity to facilitate the incorporation of output electricity from the micro-plant into an integrated power system.

In some embodiments, the medium voltage transformers are connected to a plurality of electrical conduits, and the micro-plant outputs to the plurality of electrical conduits. In some embodiments, the micro-plant is configured to provide different amounts of electricity to the different electrical conduits based at least partially on the power demand of the co-locations associated with each of the electrical conduits. In at least one example, the electricity output of the micro-plant is directed to different electrical conduits and/or at different voltages by a micro-plant controller.

In some embodiments, the micro-plant generates thermal energy (heat) and converts at least a portion of that thermal energy to electricity. The micro-plant distributes at least a portion of the output electricity to the datacenter or datacenter region to power co-locations and other resources of the datacenter. In some embodiments, the micro-plant further produces excess electricity and/or excess heat that is beyond the demands of the datacenter or datacenter region.

In some embodiments, the excess heat or thermal energy is exported to a thermal store, as described herein, for later conversion to electricity. In some embodiments, the excess heat is exported for carbon capture and/or sequestration to further lower the carbon load of the datacenter power system. In some embodiments, the excess heat is exported for local structural heating, such as for structural heating of residential homes or commercial buildings (e.g., district heat).

In some embodiments, the micro-plant produces excess electricity. In some embodiments, the excess electricity is exported to the regional power grid, such as described herein. In some embodiments, a micro-grid controller receives grid information and, based at least partially on the grid information, exports excess electricity to the regional power grid. In some embodiments, the micro-plant delivers excess electricity to other ESSs of the datacenter power system. For example, the excess electricity may power a chemical ESS. In some embodiments, the excess electricity powers an electrolyzer to produce hydrogen feedstock for a hydrogen fuel cell generator where the energy is stored in the chemical energy of the hydrogen feedstock.

In at least some embodiments, a datacenter powered by a micro-reactor and/or micro-plant generates thermal energy and electricity that can power at least a portion of the datacenter as well as be exported for additional uses.

The present disclosure relates to systems and methods for providing electrical power in a datacenter according to at least the examples provided in the clauses below:

Clause 1. A datacenter power system comprising: a co-location including a plurality of computing devices; and a micro-plant in electrical communication with the co-location to supply micro-plant electrical power to the co-location, the micro-plant including: a plurality of micro-reactors, wherein each micro-reactor is configured to produce thermal energy, and at least one generator in thermal communication with the plurality of micro-reactors configured to convert at least a portion of the thermal energy to the micro-plant electrical power.

Clause 2. The datacenter power system of clause 1, wherein each micro-reactor of the plurality of micro-reactors is configured to generate no more than 20 Megawatts of thermal energy.

Clause 3. The datacenter power system of clause 1, wherein each micro-reactor of the plurality of micro-reactors is thermally coupled to a unique generator of a plurality of generators of the micro-plant.

Clause 4. The datacenter power system of clause 1, wherein the plurality of generators is in electrical communication with an electrical manifold of the micro-plant.

Clause 5. The datacenter power system of clause 1, wherein the micro-plant further includes a thermal manifold thermally coupled to the plurality of micro-reactors.

Clause 6. The datacenter power system of clause 1, wherein at least one micro-reactor of the plurality of micro-reactors is a nuclear micro-reactor.

Clause 7. The datacenter power system of clause 1, wherein at least one micro-reactor of the plurality of micro-reactors is a fuel cell micro-reactor.

Clause 8. The datacenter power system of clause 1, wherein the micro-plant provides electrical power at a high voltage proximate a grid connection.

Clause 9. The datacenter power system of clause 1, wherein the micro-plant provides the micro-plant electrical power at a medium voltage electrically opposite a transformer from a grid connection.

Clause 10. The datacenter power system of clause 1, further comprising a thermal storage device in thermal communication with at least one micro-reactor.

Clause 11. The datacenter power system of clause 10, wherein the thermal storage device is in thermal communication with the at least one generator.

Clause 12. The datacenter power system of clause 1, further comprising at least one energy storage system (ESS) in electrical communication with the at least one generator.

Clause 13. The datacenter power system of clause 12, wherein the ESS is a chemical battery ESS.

Clause 14. The datacenter power system of clause 12, wherein the ESS is an electrolyzer of a hydrogen fuel cell generator.

Clause 15. A datacenter power system comprising: a grid connection configured to receive power from a regional power grid; one or more co-locations including a plurality of computing devices; a micro-plant in electrical communication with the grid connection and the co-location to supply micro-plant electrical power to the grid connection and the co-location, the micro-plant including: a plurality of micro-reactors, wherein each micro-reactor is configured to produce thermal energy, at least one generator in thermal communication with the plurality of micro-reactors configured to convert at least a portion of the thermal energy to the micro-plant electrical power, and a micro-plant controller in communication with the grid connection, the co-location, and the at least one generator, wherein the micro-plant controller is configured to: receive co-location demand information, receive grid information, and adjust an output of micro-plant electrical power based at least partially on the co-location demand information and the grid information.

Clause 16. The datacenter power system of clause 15, wherein adjusting the output of micro-plant electrical power includes distributing electrical power from at least one generator to an energy storage system.

Clause 17. The datacenter power system of clause 15, wherein adjusting the output of micro-plant electrical power includes changing a thermal output of at least one micro-reactor of the plurality of micro-reactors.

Clause 18. The datacenter power system of clause 15, wherein adjusting the output of micro-plant electrical power includes increasing the output based on an increase in grid pricing of the grid information.

Clause 19. The datacenter power system of clause 15, wherein adjusting the output of micro-plant electrical power includes increasing the output based on an increase in carbon load of the grid information.

Clause 20. A datacenter power system comprising: a first datacenter region including: a first co-location including a plurality of computing devices; a first micro-plant in electrical communication with a first grid connection and the co-location to supply first micro-plant electrical power to the first grid connection and the first co-location, the first micro-plant including: a plurality of micro-reactors, wherein each micro-reactor is configured to produce first thermal energy, and at least one generator in thermal communication with the plurality of micro-reactors configured to convert at least a portion of the first thermal energy to the first micro-plant electrical power; a second datacenter region including: a second co-location including a plurality of computing devices; a second micro-plant in electrical communication with a second grid connection and the second co-location to supply second micro-plant electrical power to the second grid connection and the second co-location, the second micro-plant including: a plurality of micro-reactors, wherein each micro-reactor is configured to produce second thermal energy, and at least one generator in thermal communication with the plurality of micro-reactors configured to convert at least a portion of the thermal energy to the second micro-plant electrical power; and a micro-grid controller in data communication with the regional power grid, the first datacenter region, and the second datacenter region, wherein the micro-grid controller is configured to: receive first datacenter region balance information, receive second datacenter region balance information, and adjust electrical power between the first datacenter region and the second datacenter region through the micro-grid based at least partially on the datacenter region balance information.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the scope of the present disclosure, and that various changes, substitutions, and alterations may be made to embodiments disclosed herein without departing from the scope of the present disclosure. Equivalent constructions, including functional “means-plus-function” sections are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A datacenter power system comprising:
a co-location including a plurality of computing devices; and
a micro-plant in electrical communication with the co-location to supply micro-plant electrical power to the co-location, the micro-plant including:
a plurality of micro-reactors, wherein each micro-reactor is configured to produce thermal energy, and
at least one generator in thermal communication with the plurality of micro-reactors configured to convert at least a portion of the thermal energy to the micro-plant electrical power.

2. The datacenter power system of claim 1, wherein each micro-reactor of the plurality of micro-reactors is configured to generate no more than 20 Megawatts of thermal energy.

3. The datacenter power system of claim 1, wherein each micro-reactor of the plurality of micro-reactors is thermally coupled to a unique generator of a plurality of generators of the micro-plant.

4. The datacenter power system of claim 1, wherein the micro-plant further includes a thermal manifold thermally coupled to the plurality of micro-reactors.

5. The datacenter power system of claim 1, wherein at least one micro-reactor of the plurality of micro-reactors is a nuclear micro-reactor.

6. The datacenter power system of claim 1, wherein at least one micro-reactor of the plurality of micro-reactors is a fuel cell micro-reactor.

7. The datacenter power system of claim 1, wherein the micro-plant provides electrical power at a high voltage proximate a grid connection.

8. The datacenter power system of claim 1, wherein the micro-plant provides the micro-plant electrical power at a medium voltage electrically opposite a transformer from a grid connection.

9. The datacenter power system of claim 1, further comprising a thermal store device in thermal communication with at least one micro-reactor.

10. The datacenter power system of claim 9, wherein the thermal store includes a sand thermal mass.

11. The datacenter power system of claim 9, wherein the thermal store is in thermal communication with the at least one generator.

12. The datacenter power system of claim 1, further comprising at least one energy storage system (ESS) in electrical communication with the at least one generator.

13. The datacenter power system of claim 12, wherein the ESS is a chemical battery ESS.

14. The datacenter power system of claim 12, wherein the ESS includes an electrolyzer.

15. A datacenter power system comprising:
a grid connection configured to receive power from a regional power grid;
one or more co-locations including a plurality of computing devices;
a micro-plant in electrical communication with the grid connection and the co-location to supply micro-plant electrical power to the grid connection and the co-location, the micro-plant including:
a plurality of micro-reactors, wherein each micro-reactor is configured to produce thermal energy,
at least one generator in thermal communication with the plurality of micro-reactors configured to convert at least a portion of the thermal energy to the micro-plant electrical power, and
a micro-plant controller in communication with the grid connection, the co-location, and the at least one generator, wherein the micro-plant controller is configured to:
receive co-location demand information,
receive grid information, and
adjust an output of micro-plant electrical power based at least partially on the co-location demand information and the grid information.

16. The datacenter power system of claim 15, wherein adjusting the output of micro-plant electrical power includes distributing electrical power from at least one generator to an energy storage system.

17. The datacenter power system of claim 15, wherein adjusting the output of micro-plant electrical power includes changing a thermal output of at least one micro-reactor of the plurality of micro-reactors.

18. The datacenter power system of claim 15, wherein adjusting the output of micro-plant electrical power includes increasing the output based on an increase in grid pricing of the grid information.

19. The datacenter power system of claim 15, wherein adjusting the output of micro-plant electrical power includes increasing the output based on an increase in carbon load of the grid information.

20. A datacenter power system comprising:
a first datacenter region including:
a first co-location including a plurality of computing devices;
a first micro-plant in electrical communication with a first grid connection to a regional power grid and the first co-location to supply first micro-plant electrical power to the first grid connection and the first co-location, the first micro-plant including:
a plurality of micro-reactors, wherein each micro-reactor is configured to produce first thermal energy, and
at least one generator in thermal communication with the plurality of micro-reactors configured to convert at least a portion of the first thermal energy to the first micro-plant electrical power;
a second datacenter region including:
a second co-location including a plurality of computing devices;
a second micro-plant in electrical communication with a second grid connection to the regional power grid and the second co-location to supply second micro-plant electrical power to the second grid connection and the second co-location, the second micro-plant including:
a plurality of micro-reactors, wherein each micro-reactor is configured to produce second thermal energy, and
at least one generator in thermal communication with the plurality of micro-reactors configured to convert at least a portion of the thermal energy to the second micro-plant electrical power; and
a micro-grid controller in data communication with the regional power grid, the first datacenter region, and the second datacenter region, wherein the micro-grid controller is configured to:
receive first datacenter region balance information,
receive second datacenter region balance information, and
adjust electrical power between the first datacenter region and the second datacenter region through the micro-grid based at least partially on the datacenter region balance information.
